(19) United States
(12) Patent Application Publication
(10) Pub. No.: US 2019/0035604 A1
(43) Pub. Date: Jan. 31, 2019

(54) SOLID-STATE SOURCE OF ATOMIC SPECIE FOR ETCHING

(71) Applicant: Tokyo Electron Limited, Tokyo (JP)

(72) Inventors: Peter Ventzek, Austin, TX (US); Alok Ranjan, Austin, TX (US)

(21) Appl. No.: 16/043,960

(22) Filed: Jul. 24, 2018

Related U.S. Application Data
(60) Provisional application No. 62/536,723, filed on Jul. 25, 2017.

(51) Int. Cl. H01J 37/32

(52) U.S. Cl. CPC H01J 37/3244; H01J 2237/006; H01J 2237/3341

(57) ABSTRACT

An etching system, a solid state source for supplying an atomic specie, and a method of operating are described. The system includes: a processing chamber for treating a substrate in a gas-phase chemical environment; a substrate holder for supporting the substrate in the processing chamber; and a solid state source of an atomic specie coupled to the processing chamber, and configured to supply the atomic specie to the processing chamber when treating the substrate. The processing chamber can facilitate a gas-phase, plasma-containing or non-plasma-containing environment.

### CROSS-REFERENCE SECTION

This application claims priority to Provisional Patent Application No. 62/536,723, entitled, SOLID-STATE SOURCE OF ATOMIC SPECIE FOR ETCHING, filed Jul. 25, 2017; the disclosure of which is expressly incorporated herein, in its entirety, by reference.

### FIELD OF INVENTION

The invention relates to an apparatus and method for etching, and more particularly, a precision etch apparatus and technique for etching a thin film for electronic device applications.

### BACKGROUND OF THE INVENTION

The manufacture of magneto-resistive random access memory (MRAM) devices presents many challenges to device manufacturers and equipment suppliers, particularly with patterning the complex metal stacks. One of the major hindrances in the processing of MRAM features with smart vertical sidewalls derives from the origin of the carbon source used for their passivation. Carbon is usually delivered with hydrogen; however, hydrogen can damage the electrical characteristics of the MRAM device. Furthermore, carbon, introduced as a compound into plasma, dissociates into constituents of the compound in a relatively uncontrollable manner. As a result, the byproducts of uncontrollable dissociation can form polymer layers that inhibit robust patterning of metal stacks with proper profile control.

### SUMMARY

Techniques herein pertain to device fabrication using precision etch techniques.

According to an embodiment, an etching system is described. The system includes: a processing chamber for treating a substrate in a gas-phase chemical environment; a substrate holder for supporting the substrate in the processing chamber; and a solid state source of an atomic specie coupled to the processing chamber, and configured to supply the atomic specie to the processing chamber when treating the substrate. The processing chamber can facilitate a gas-phase, plasma-containing or non-plasma-containing environment.

According to another embodiment, an atomic specie source is described. The source includes: a source chamber configured to be coupled to an etching system; and a solid state source of an atomic specie configured to generate the atomic specie within the source chamber.

According to yet another embodiment, a method of etching is described. The method includes: disposing a substrate in a processing chamber of an etching system; supplying an atomic specie from a solid state source that is coupled to the processing chamber, and configured to supply the atomic specie to the processing chamber when treating the substrate; and etching the substrate by exposing the substrate to a reactive gas in the processing chamber.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

In the accompanying drawings:

FIG. 1 illustrates a method of pattern etching according to the prior art;

FIG. 2 illustrates a method of pattern etching according to an embodiment;

FIGS. 3A and 3B illustrate etching systems according to embodiments;

FIG. 4 illustrates a method of etching a substrate according to an embodiment;

FIG. 5 provides a flow chart illustrating a method of etching a substrate according to an embodiment;

FIG. 6 illustrates a solid state source according to another embodiment; and

FIGS. 7A through 7D provide schematic illustrations of plasma processing systems for performing the method of etching according to various embodiments.

### DETAILED DESCRIPTION

Techniques herein pertain to device fabrication using precision etch techniques. Several instances manifest in semiconductor manufacturing in both logic and memory device. As an example, it is important to transfer patterns into the metal stacks that form magneto-resistive random access memory (MRAM) with accurate control of the profile.

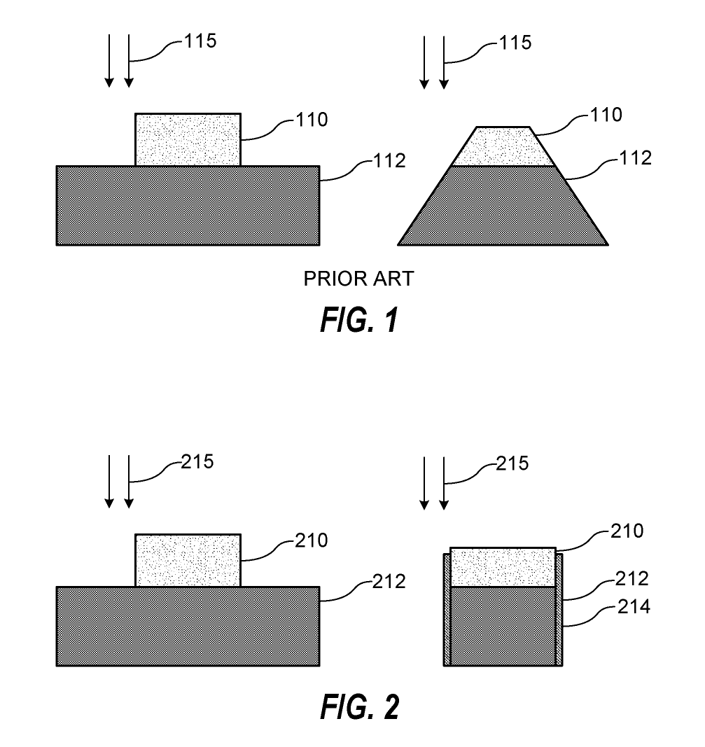

As noted above, one of the major hindrances in the processing of MRAM features with smart vertical sidewalls derives from the origin of the carbon source used for their passivation. For example, FIG. 1 illustrates a method of patterning an MRAM stack 112, wherein a patterned mask 110 overlies the MRAM stack 112, and the pattern is extended into MRAM stack 112 using a conventional ion milling process. However, as shown, the ion milling process has poor profile control, leading to a tapered stack.

As another example, FIG. 2 illustrates a method of patterning an MRAM stack 212, wherein a patterned mask 210 overlies the MRAM stack 212, and the pattern is extended into MRAM stack 212 using an ion-assisted etching process. For the purpose of passivation during the ion-assisted etching process, among others, carbon can be delivered with hydrogen or other elements; however, hydrogen and/or other elements (O or N, e.g.) can damage the electrical characteristics of the MRAM device. For instance, the tunnel magneto-resistance (TMR) is known to deteriorate in some cases. Furthermore, carbon, introduced as a compound into plasma, dissociates into constituents of the compound in a relatively uncontrollable manner. As a result, the byproducts of uncontrollable dissociation can form polymer layers that inhibit robust patterning of metal stacks with proper profile control.

Therefore, according to embodiments described herein, carbon in its atomic form, and/or other atomic species (e.g., B, Si, Ge, etc.), is introduced into a chemical environment, with or without plasma, to passivate select surfaces or increase/enhance etch selectivity. However, the addition of carbon can be challenging, since carbon is not volatile and cannot be “bubbled” in its pure form in an evaporator. As disclosed herein, the challenges associated with introducing carbon into the chemical environment can be solved by ablating carbon from any manner of carbon source using an electron beam as an ablation mechanism. The carbon plasma above the ablation source can be mixed with a carrier gas, and introduced into a processing chamber, wherein the degree of ionization of the carbon and carrier mixture can be controlled.

Flow management and power, as well as other know control parameters in an etching system, can be used to control the uniformity of the atomic carbon species onto the substrate. And, the amount of carbon can be precisely delivered and metered using net ablation source (e.g., electron beam) power and carrier gas flow rate, as control parameters, for example. The flow of reactive gases and/or inert gases in the processing chamber can be used to control the partial pressure, and therefore, the flux of neutral carbon species, including the relative carbon neutral flux. Source power or an auxiliary ionization mechanism can control the ratio of the neutral carbon to ionized carbon flux to the substrate.

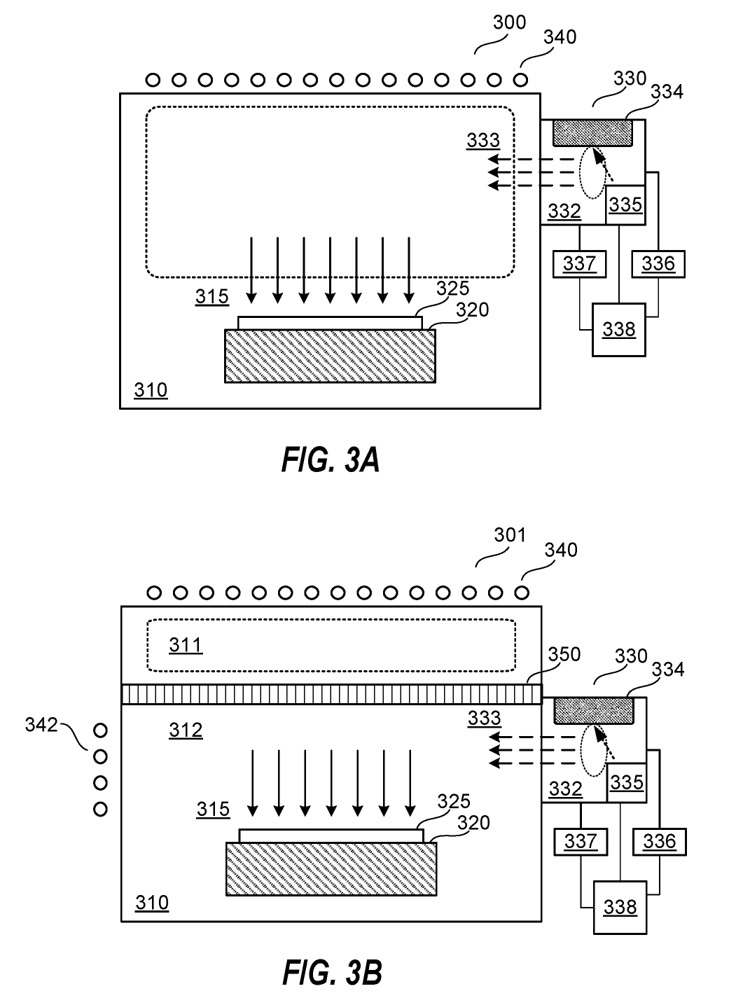

Referring now to FIGS. 3A and 3B, etching systems are described according to embodiments. As shown in FIG. 3A, etching system 300 includes a processing chamber 310 for treating a substrate 325 in a gas-phase chemical environment 315, a substrate holder 320 for supporting the substrate 325 in the processing chamber 310, and a solid state source 330 of an atomic specie coupled to the processing chamber 310, and configured to supply the atomic specie to the processing chamber 310 when treating the substrate 325. The solid state source 330 includes a source chamber 332, within which a solid state target 334 is mounted for supplying the atomic specie, and an ablation mechanism 335 arranged to heat and sublime the solid state target 334, and form the atomic specie in the gas phase. According to one embodiment, the ablation mechanism 335 includes an electron source. The electron source can include an electron gun source commercially available from Kimball Physics, Inc. In an alternative embodiment, the ablation mechanism 335 includes a laser.

The solid state source 330 can include a carrier gas supply 336 arranged to supply a carrier gas for flowing the atomic specie into the processing chamber 310. The carrier gas can include a noble gas, such as Ar. Furthermore, the solid state source 330 can include a controller 338 programmably configured to communicate with the ablation mechanism 335 and the carrier gas supply 336 to control an amount of the atomic specie delivered to the processing chamber 310. A vacuum pumping system 337, independent of the processing chamber 310, can be used to evacuate source chamber 332. The atomic specie can be selected from the group consisting of carbon, boron, silicon, and germanium. For example, the atomic specie can include carbon, and the solid state target 334 can be composed of graphite. However, other sources of carbon are contemplated. Solid state source 330 can be operated in pulsed (modulated), or continuous wave mode.

Etching system 300 can include a plasma generating mechanism 340 coupled to the processing chamber 310, and configured to generate plasma species in the chemical environment 315. For example, the plasma generating mechanism 340 can include a capacitively coupled plasma generating element, an inductively coupled plasma generating element (as shown), a microwave frequency plasma generating element, or a surface wave antenna, or a combination of two or more thereof. In addition to generating plasma, the substrate holder 320 can be configured to electrically bias substrate 325. The plasma generating mechanism 340, and the electrical bias of substrate holder 320 can be operated in pulsed (modulated), or continuous wave mode. Modulation of the solid state source 330, the plasma generating mechanism 340, the electrical bias of substrate holder 320, gas flow rates, etc. can be used to tailor the relative amounts of neutral and charged species directed to the substrate 325 during processing.

As shown in FIG. 3B, etching system 301 is similar to the system of FIG. 3A, yet further includes a filter mechanism 350 disposed within the processing chamber 310, and arranged to divide the processing chamber 310 into a first region 311 and a second region 312, wherein the substrate 325 resides in the second region 312, and wherein the filter mechanism 350 mediates the flow of species between the first and second regions 311, 312. The solid state source 330 can be coupled to the processing chamber 310, and arranged to introduce the atomic specie into the second region 312 of the processing chamber 310, as shown. Alternatively, the solid state source 330 can be coupled to the processing chamber 310, and arranged to introduce the atomic specie into the first region 311 of the processing chamber 310. Etching system 301 can further include another plasma generating mechanism 342 coupled to the processing chamber 310, and configured to generate plasma in the second region 312. The filter mechanism 350 may be designed to mediate the flow and/or exchange of charger and/or neutral species between the first and second regions 311, 312.

In FIG. 5, a method of etching is described according to another embodiment. Flow chart 500 illustrates a method beginning in 510 with disposing a substrate in a processing chamber of an etching system. The method includes, in 520, supplying an atomic specie from a solid state source that is coupled to the processing chamber, and configured to supply the atomic specie to the processing chamber when treating the substrate, and in 530, etching the substrate by exposing the substrate to a reactive gas in the processing chamber.

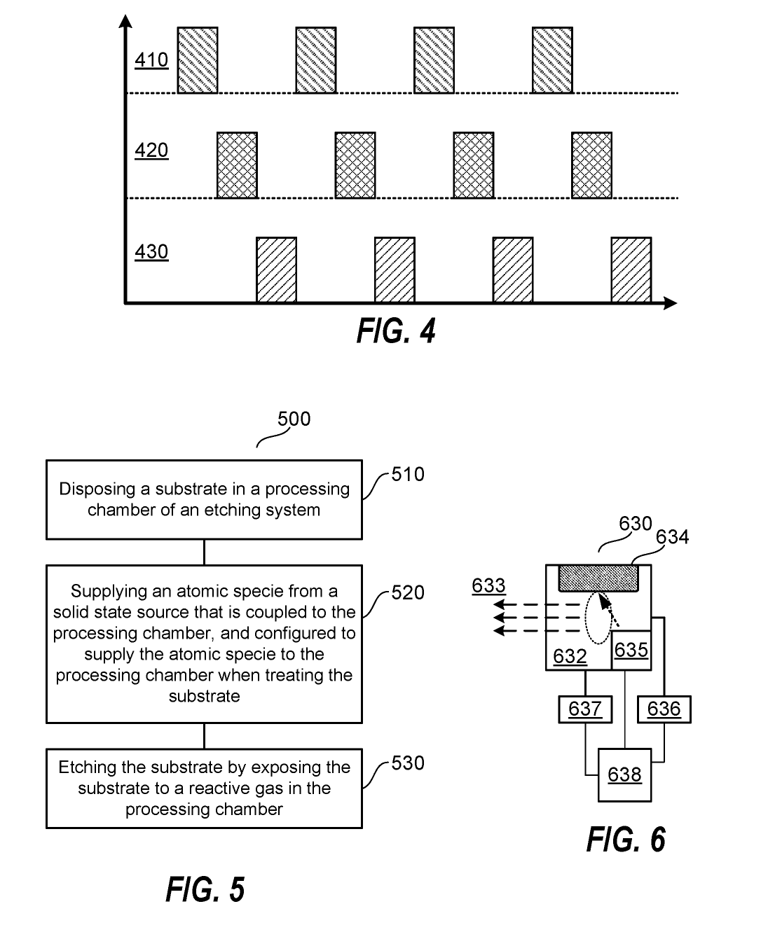

The method of etching can further include passivating a surface of the substrate during the supplying of the atomic specie, and thereafter, optionally purging the processing chamber. The steps of passivating (410), purging (420), and etching (430) can be performed alternatingly and cyclically (see FIG. 4). During at least one of the steps of passivating, purging, and etching, the substrate can be electrically biased. Additionally, during at least one of the steps of passivating, purging, and etching, plasma can be generated in the processing chamber.

In some embodiments, a filter mechanism can be disposed within the processing chamber, and arranged to divide the processing chamber into a first region and a second region, wherein the substrate resides in the second region, and wherein the filter mechanism mediates the flow of species between the first and second regions. Plasma can be generated in the first region, or the second region, or both the first and second regions. The solid state source is arranged to supply the atomic specie to the first region, or the second region, or both the first and second regions.

According to another embodiment, a solid state source 630 of an atomic specie is shown in FIG. 6. The solid state source 630 is configured to be coupled to an etching system, and configured to supply the atomic specie to the etching system. The solid state source 630 includes a source chamber 632, within which a solid state target 634 is mounted for supplying the atomic specie, and an ablation mechanism 635 arranged to heat and sublime the solid state target 634, and form the atomic specie in the gas phase. According to one embodiment, the ablation mechanism 635 includes an electron source. In an alternative embodiment, the ablation mechanism 635 includes a laser.

The solid state source 630 can include a carrier gas supply 636 arranged to supply a carrier gas for delivering the atomic specie. The carrier gas can include a noble gas, such as Ar. Furthermore, the solid state source 630 can include a controller 638 programmably configured to communicate with the ablation mechanism 635 and the carrier gas supply 636 to control an amount of the atomic specie delivered to the the etching system. A vacuum pumping system 637 can be used to evacuate source chamber 632. The atomic specie can be selected from the group consisting of carbon, boron, silicon, and germanium. For example, the atomic specie can include carbon, and the solid state target 634 can include can be composed of graphite. Solid state source 630 can be operated in pulsed (modulated), or continuous wave mode.

While the solid state source 630 is described in the context of coupling to an etching system, the solid state source 630 can be configured to couple to a deposition system, such as a physical vapor deposition (PVD) system, a chemical vapor deposition (CVD) system), an atomic layer deposition (ALD) system, area selective deposition (ASD) system, etc. Other processing systems are contemplated, such as thermal processing systems, cleaning systems, beam systems (e.g., charged particle beam, ion beam, gas cluster jet, gas cluster ion beam, cryo-aerosol jets, etc.), etc.

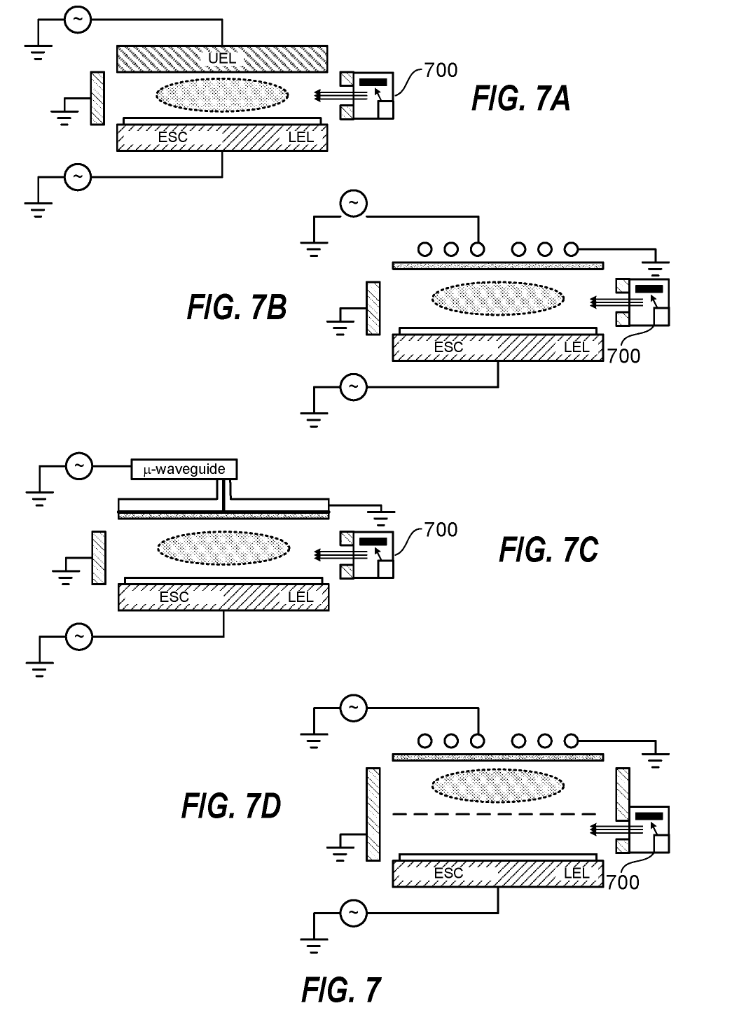

FIGS. 7A through 7D provide several plasma processing systems, which may serve as etching systems, that may be used to facilitate plasma-excitation of a process gas. FIG. 7A illustrates a capacitively coupled plasma (CCP) system, wherein plasma is formed proximate a substrate between an upper plate electrode (UEL) and a lower plate electrode (LEL), the lower electrode also serving as an electrostatic chuck (ESC) to support and retain the substrate. Plasma is formed by coupling radio frequency (RF) power to at least one of the electrodes. As shown in FIG. 7A, RF power is coupled to both the upper and lower electrodes, and the power coupling may include differing RF frequencies. Alternatively, multiple RF power sources may be coupled to the same electrode. Moreover, direct current (DC) power may be coupled to the upper electrode.

FIG. 7B illustrates an inductively coupled plasma (ICP) system, wherein plasma is formed proximate a substrate between an inductive element (e.g., a planar, or solenoidal/helical coil) and a lower plate electrode (LEL), the lower electrode also serving as an electrostatic chuck (ESC) to support and retain the substrate. Plasma is formed by coupling radio frequency (RF) power to the inductive coupling element. As shown in FIG. 7B, RF power is coupled to both the inductive element and lower electrode, and the power coupling may include differing RF frequencies.

FIG. 7C illustrates a surface wave plasma (SWP) system, wherein plasma is formed proximate a substrate between a slotted plane antenna and a lower plate electrode (LEL), the lower electrode also serving as an electrostatic chuck (ESC) to support and retain the substrate. Plasma is formed by coupling radio frequency (RF) power at microwave frequencies through a waveguide and coaxial line to the slotted plane antenna. As shown in FIG. 7C, RF and/or microwave power is coupled to both the slotted plane antenna and lower electrode, and the power coupling may include differing RF frequencies.

FIG. 7D illustrates remote plasma system, wherein plasma is formed in a region remote from a substrate and separated from the substrate by a filter arranged to impede the transport of charged particles from the remote plasma source to a processing region proximate the substrate. The substrate is supported by a lower plate electrode (LEL) that also serves as an electrostatic chuck (ESC) to retain the substrate. Plasma is formed by coupling radio frequency (RF) power to a plasma generating device adjacent the remotely located region. As shown in FIG. 7D, RF power is coupled to both the plasma generating device adjacent the remote region and lower electrode, and the power coupling may include differing RF frequencies.

The etching systems of FIGS. 7A through 7D include a solid state source 700 to supply an atomic specie to each etching system. While the embodiments illustrated in FIGS. 7A through 7D include plasma processing systems, non-plasma processing systems are contemplated. Other embodiments are contemplated including both combinations and variations of the systems described.

In the claims below, any of the dependents limitations can depend from any of the independent claims.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. An etching system, comprising:
a processing chamber for treating a substrate in a gas-phase chemical environment;
a substrate holder for supporting the substrate in the processing chamber; and
a solid state source of an atomic specie coupled to the processing chamber, and configured to supply the atomic specie to the processing chamber when treating the substrate.

2. The system of claim 1, wherein the solid state source includes:
a solid state target for supplying the atomic specie; and
an ablation mechanism arranged to heat and sublime the solid state target, and form the atomic specie in the gas phase.

3. The system of claim 2, wherein the ablation mechanism includes an electron source, or a laser, or a combination thereof.

4. The system of claim 2, wherein the solid state source includes a carrier gas supply arranged to supply a carrier gas for flowing the atomic specie into the processing chamber.

5. The system of claim 4, wherein the solid state source includes a controller programmably configured to communicate with the ablation mechanism and the carrier gas supply to control an amount of the atomic specie delivered to the processing chamber.

6. The system of claim 2, wherein the solid state source includes a vacuum pumping system, independent of the processing chamber.

7. The system of claim 1, wherein the atomic specie is selected from the group consisting of carbon, boron, silicon, and germanium.

8. The system of claim 1, further comprising:
a plasma generating mechanism coupled to the processing system, and configured to generate plasma species in the chemical environment.

9. The system of claim 8, wherein the plasma generating mechanism includes a capacitively coupled plasma generating element, an inductively coupled plasma generating element, a microwave frequency plasma generating element, or a surface wave antenna, or a combination of two or more thereof.

10. The system of claim 8, further comprising:
a filter mechanism disposed within the processing chamber, and arranged to divide the processing chamber into a first region and a second region, wherein the substrate resides in the second region, and wherein the filter mechanism mediates the flow of species between the first and second regions.

11. An atomic specie source, comprising:
a source chamber configured to be coupled to an etching system; and
a solid state source of an atomic specie configured to generate the atomic specie within the source chamber.

12. The source of claim 11, wherein the solid state source includes:
a solid state target for supplying the atomic specie; and
an ablation mechanism arranged to heat and sublime the solid state target, and form the atomic specie in the gas phase.

13. The source of claim 12, wherein the ablation mechanism includes an electron source, or a laser, or a combination thereof.

14. The source of claim 12, wherein the solid state source includes a carrier gas supply arranged to supply a carrier gas for flowing the atomic specie into the processing chamber.

15. The source of claim 14, wherein the solid state source includes a controller programmably configured to communicate with the ablation mechanism and the carrier gas supply to control an amount of the atomic specie delivered to the processing chamber.

16. The system of claim 12, wherein the solid state source includes a vacuum pumping system, independent of the processing chamber.

17. The system of claim 11, wherein the atomic specie is selected from the group consisting of carbon, boron, silicon, and germanium.

18. A method of etching, comprising:
disposing a substrate in a processing chamber of an etching system;
supplying an atomic specie from a solid state source that is coupled to the processing chamber, and configured to supply the atomic specie to the processing chamber when treating the substrate; and
etching the substrate by exposing the substrate to a reactive gas in the processing chamber.

19. The method of claim 18, further comprising:
passivating a surface of the substrate during the supplying of the atomic specie;
after passivating, purging the processing chamber; and
optionally, alternatingly and cyclically performing the steps of passivating, purging, and etching,
wherein the atomic specie is selected from the group consisting of carbon, boron, silicon, and germanium.

20. The method of claim 18, further comprising:
generating plasma in the processing chamber during at least one of the steps of passivating, purging, and etching; and
electrically biasing the substrate during at least one of the steps of passivating, purging, and etching.
